(19) United States
(12) Patent Application Publication
(10) Pub. No.: US 2026/0088655 A1
(43) Pub. Date: Mar. 26, 2026

(54) WIRELESS CHARGING DEVICE WITH HEAT DISSIPATION STRUCTURE

(71) Applicant: E-LEAD ELECTRONIC CO., LTD., CHANGHUA (TW)

(72) Inventor: Stephen CHEN, CHANGHUA (TW)

(21) Appl. No.: 19/058,962

(22) Filed: Feb. 20, 2025

(30) Foreign Application Priority Data
Sep. 20, 2024 (TW) 113210224

(51) Int. Cl. H02J 50/10; H02J 50/90; H05K 7/20

(52) U.S. Cl. CPC H02J 50/10; H02J 50/90; H05K 7/20909

(57) ABSTRACT

A wireless charging device with a heat dissipation structure comprises a first housing and a second housing that are mutually combined. The first housing includes at least one charging pad, at least one intake grille, and at least one exhaust assembly. The at least one charging pad protrudes from an outer surface of the first housing and incorporates a heat sink for dissipating thermal energy generated during operation. A fan is positioned between the first housing and the second housing and generates an airflow into the interior of the housing. The airflow is then directed through an airflow channel toward the exhaust assembly of the first housing and an air discharge zone of the second housing. This configuration enables simultaneous cooling of the heat sink and a mobile device, achieving efficient heat dissipation.

### FIELD OF INVENTION

The present disclosure relates to a wireless charging device, in particular a wireless charging device with a heat dissipation structure.

### BACKGROUND OF THE PRESENT INVENTION

With the accelerating pace of technological innovation, mobile devices have become an integral part of modern life. However, their extensive use requires frequent recharging, often via in-car chargers or other power sources. To enhance the user experience, wireless charging technology has emerged as a preferred alternative to conventional wired charging. By eliminating the need for cumbersome cables, users can charge their devices by simply placing them on a charging pad, which initiates automatic magnetic alignment and power transfer. With the advancement of fast charging technology, wireless charging currents are dynamically managed by the mobile device. However, optimal charging efficiency is often unattainable due to battery overheating. Overheating poses serious risks, including accelerated degradation of battery life, potential damage to internal components and, in extreme scenarios, explosions. As such, maintaining the battery temperature below a critical threshold of 38° C. during high-power charging has therefore become a key objective in the development of advanced wireless charging systems.

Furthermore, the charging coil within a wireless charging device inherently generates heat during operation, requiring the incorporation of heat dissipation mechanisms such as heat sinks and cooling fans. These components are intended to prevent thermal energy from being transferred to the battery of the mobile device. However, under high-power charging conditions, the rate of heat generation often exceeds the dissipation capacity of these systems. As a result, both the charging device and the mobile device tend to overheat simultaneously. This not only undermines the efficiency of the charging process, but also accelerates wear and tear, potentially shortening the operational life of both devices.

A critical component of the mobile device with respect to wireless charging is a receiving coil located on the back of the device. This coil is tasked with converting magnetic energy from the charging pad into electrical current for battery charging, and this energy conversion process can generate significant heat. Similarly, the subsequent conversion of electrical current into chemical energy for storage in the battery also generates another layer of heat. As a result, the back of the mobile device requires additional cooling measures, such as the integration of fans to assist in heat dissipation. Effectively managing the heat generated by both the wireless charging equipment and the mobile device has therefore become a key technical issue, requiring innovative technical solutions that can provide sufficient airflow optimization to address this issue.

### SUMMARY OF THE PRESENT INVENTION

To address the limitations of existing technologies, the purpose of the present disclosure is to provide a wireless charging device designed to optimize the distribution of airflow generated by a fan. This distribution is specifically aimed at directing the airflow toward both the heat sinks and the mobile devices, achieving efficient and comprehensive thermal management.

In accordance with this purpose, the invention introduces a wireless charging device with an integrated heat dissipation structure. The device comprises a housing characterized in that: the housing comprises at least one charging pad, at least one intake grille, and at least one exhaust assembly. The charging pad is configured to protrude from an outer surface of the housing and includes a wireless charging coil module and a heat sink, with the heat sink positioned on one side of the wireless charging coil module. A fan is positioned within the housing in alignment with the intake grille. In addition, an airflow guiding structure is incorporated within the housing, comprising an airflow divider and an airflow channel. The airflow divider, located adjacent to the fan, includes at least one intake port and a divider outlet. This configuration divides the airflow generated by the fan into multiple streams, with one stream directed toward the divider outlet and another directed toward the intake port. Wherein, the airflow channel is positioned inside the housing and connects the intake port to the exhaust assembly.

The housing further comprises a first housing and a second housing combined with each other. The at least one charging pad includes an alignment ring and a protective lid. The alignment ring extends vertically from an outer surface of the first housing in a direction opposite the second housing, while the protective lid is mounted on the alignment ring to form an accommodation space with the alignment ring, and the wireless charging coil module is positioned within this accommodation space.

The second housing includes a fan mount and at least one air discharge zone located on two sides of the second housing, respectively. The location of the fan mount corresponds to the position of the intake grille.

The fan mount has a mounting plate extending outward from the second housing in a direction opposite the first housing. The mounting plate includes a guide surface and a support surface, which form an angle therebetween. The guide surface is inclined relative to the second housing, and the fan is mounted on the support surface.

The at least one exhaust assembly has an airflow guide panel extending vertically from an outer surface of the first housing in a direction opposite the second housing. The airflow guide panel has a surface with multiple exhaust vents arranged in an array form on either the left or right side of the at least one charging pad.

The protrusion height of the exhaust assembly is designed to be lower than that of the charging pad.

The surface of the airflow guide panel includes the multiple exhaust vents configured in a circular pattern, the exhaust vents being positioned to encircle the charging pad.

The at least one airflow channel is implemented as an ventilation channel.

The ventilation channel includes at least one plate, the at least one plate being either assembled or integrally formed on an inner surface of the housing.

The airflow channel includes a bottom plate and a side plate extending vertically from the bottom plate. One end of the side plate forms the adjacent intake port and divider outlet.

The multiple exhaust vents of the at least one exhaust assembly are positioned on an upper surface of the housing.

The number of both the at least one exhaust assembly and the at least one airflow channel is two, each exhaust assembly including the multiple exhaust vents arranged in an array. The two exhaust assemblies are symmetrically positioned on the left and right sides of the at least one charging pad, and the two airflow channels are symmetrically positioned to align with the two exhaust assemblies.

The number of both the at least one charging pad and the at least one intake grille is two. The number of both the at least one exhaust assembly and the at least one airflow channel is one. The exhaust assembly includes the multiple exhaust vents formed on one side of the two charging pads, respectively.

The number of the at least one intake grille is two. The fan mount is positioned correspondingly between the two intake grilles, with two flow guide plates configured within the housing to correspond to the two intake grilles.

### BRIEF DESCRIPTION OF THE DRAWINGS

FIG. 1 is a schematic view of the first embodiment of the present disclosure.

FIG. 2 is an exploded view showing the components of the first embodiment of the present disclosure.

FIG. 3 is a sectional view taken along line 3-3 in FIG. 1.

FIG. 4 is a sectional view taken along line 4-4 in FIG. 1.

FIG. 5 is a schematic view showing the inner surface of the second housing of the first embodiment.

FIG. 6 is a schematic view showing the airflow channel of the first embodiment.

FIG. 7 is a schematic view of the second embodiment of the present disclosure.

FIG. 8 is a schematic view showing the inner surface of the first housing of the second embodiment.

FIG. 9 is a schematic view showing the inner surface of the second housing of the second embodiment.

FIG. 10 is a sectional view taken along line 10-10 in FIG. 7.

FIG. 11 is a sectional view taken along line 11-11 in FIG. 7.

### DETAILED DESCRIPTION OF THE PREFERRED EMBODIMENTS

In order to clearly describe the specific implementation methods, structure, and achieved effects of the present disclosure, the following embodiments are provided with reference to the drawings:

The directional descriptions such as “front,” “rear,” “up,” “down,” “left,” and “right” mentioned in this text are intended solely for ease of understanding. The present disclosure is not limited to these orientations and may be adapted as required. In the embodiments described herein, the front-rear direction is determined by the installation orientation between a wireless charging device 100, 200 and an electronic device. The up-down direction refers to the vertical axis of the wireless charging device 100, 200, while the left-right direction corresponds to its horizontal axis.

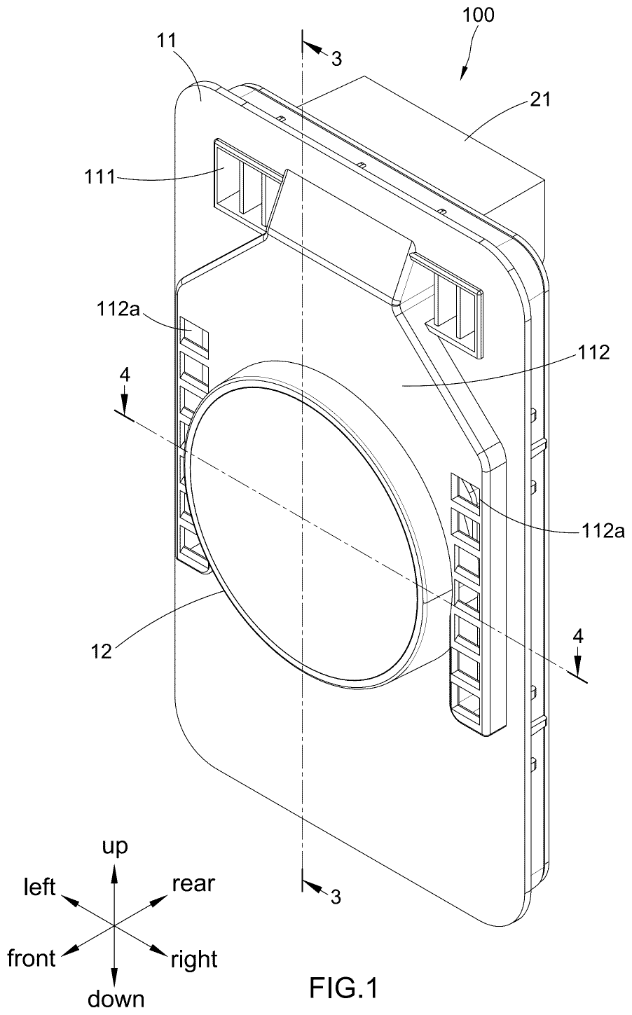

Refer to FIGS. 1 to 6, which show a first embodiment of the wireless charging device 100 designed with a heat dissipation structure. This device comprises a housing formed by the integration of a first housing 11 and a second housing 21. The connection between the first housing 11 and the second housing 21 employs interlocking mechanisms across in all embodiments of the present disclosure. However, the invention is not limited to this approach, as alternative combination methods may also be implemented.

The first housing 11 comprises a charging pad 12, an intake grille 111, and at least one exhaust assembly. The charging pad 12 is centrally positioned within the first housing 11 and includes a vertically projecting alignment ring 121 extending outwardly from an outer surface of the first housing 11 opposite the second housing 21, and a protective lid 122 is mounted on the alignment ring 121, together forming an accommodation space.

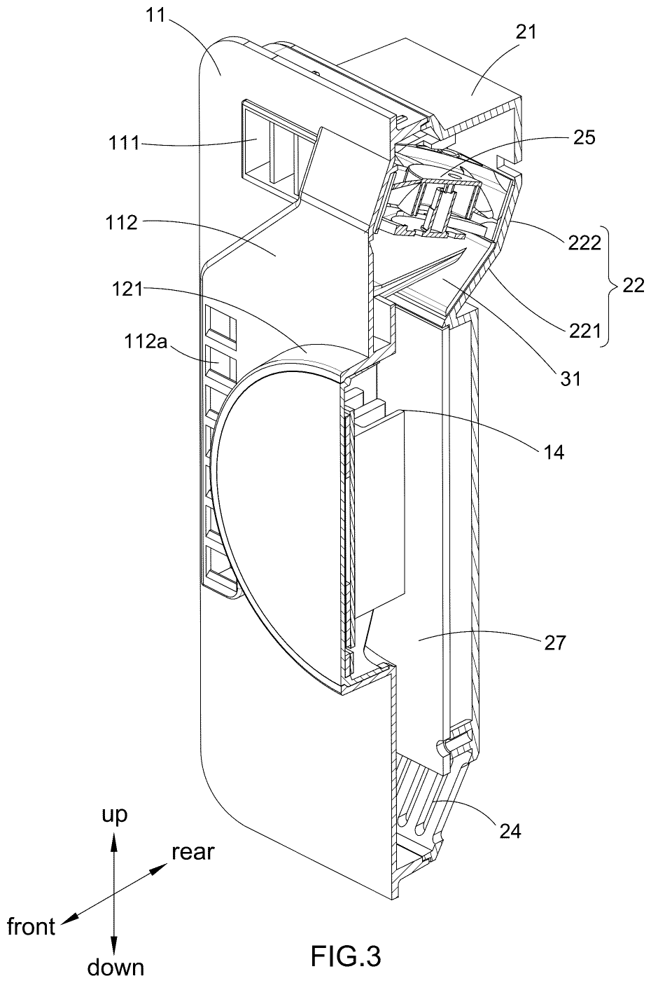

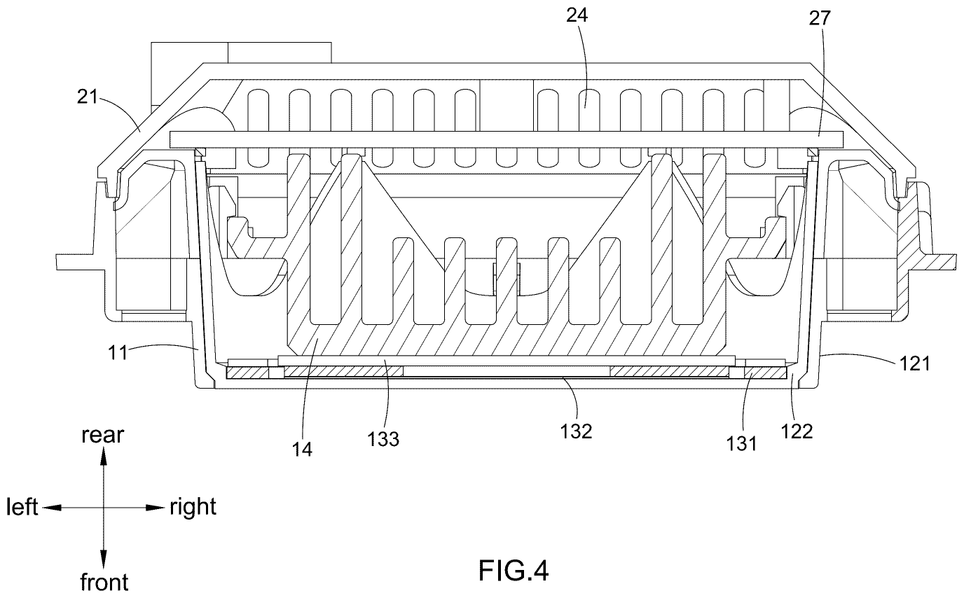

Refer to FIGS. 3 and 4, which show the integration of a wireless charging coil module 13 within the accommodation space. The wireless charging coil module 13 conforms to the Magsafe standard specifications and comprises a magnetic ring 131, an electromagnetic shielding member 132, and a wireless charging coil 133, all of which are positioned behind the protective lid 122. The magnetic ring 131 encircles the electromagnetic shielding member 132 and facilitates magnetic alignment with mobile devices. Positioned behind the electromagnetic shielding member 132, the wireless charging coil 133 generates the inductive charging field, while the electromagnetic shielding member 132 mitigates the interference from the magnetic field generated by the magnetic ring 131. A heat sink 14 positioned behind the wireless charging coil 133, effectively dissipates the heat generated by the wireless charging coil module 13, thereby enhancing the thermal management efficiency. In various embodiments, the heat sink 14 may include, but is not limited to, heat sink fins for this purpose.

In addition, the exhaust assembly includes at least one airflow guide panel 112, which extends vertically from an outer surface of the first housing 11 in a direction opposite the second housing 21. The airflow guide panel 112 is equipped with an array of exhaust vents 112a, which are positioned on either the left or right side of the charging pad 12. In alternative embodiments, the exhaust assembly may have multiple exhaust vents 112a arranged in an array form on the surface of the first housing 11.

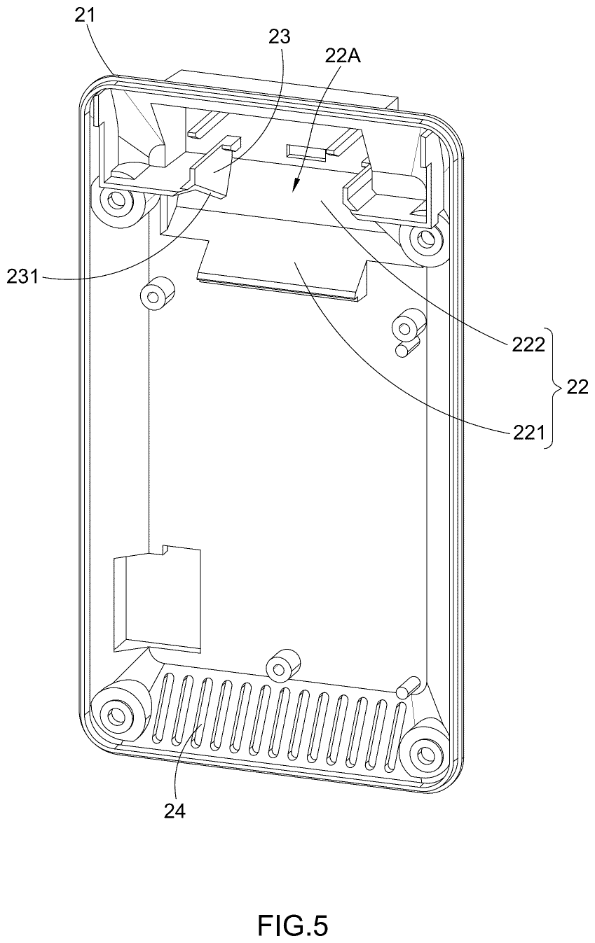

Refer to FIGS. 3 and 5, which show the second housing 21 having an fan mount 22A and a air discharge zone 24 respectively located on upper and lower sides of the second housing. The fan mount 22A is implemented as a mounting plate 22 extending outward from the second housing 21 opposite the first housing 11. The mounting plate 22 includes a guide surface 221 and a support surface 222 forming an angle of more than 100 degrees, and the guide surface 221 is configured to be inclined relative to the second housing 21. This inclined configuration of the guide surface 221 minimizes air resistance and optimizes airflow paths, thereby significantly enhancing heat dissipation efficiency.

At least one stabilizer 23 is vertically disposed at the middle position of the support surface 222 of the mounting plate 22. Each stabilizer 23 includes an inclined surface 231, which ensures the stabilization of a fan 25. In this embodiment, two stabilizers 23 are symmetrically positioned on the left and right sides of the support surface 222, and the fan 25 is mounted against their inclined surfaces 231. The fan mount 22A corresponds to the intake grille 111, which introduces an external airflow and is equipped with a grille to prevent the ingress of foreign objects, thus ensuring uninterrupted fan operation. In addition, a circuit board 27 is affixed to the inner surface of the second housing 21 and provides an electrical connection to the fan 25. In alternative embodiments, the fan mount 22A may be integrated into the inner surface of the first housing 11, and the fan 25 may be secured to either the first or second housing 11, 21 using fasteners.

Within the housing, an airflow guiding structure 30 is configured, which has multiple plates forming internal channel boundaries. This structure also includes at least one airflow channel and an airflow divider 31. The airflow channel serves to connect an intake port 32 to the exhaust assembly, which comprises a bottom plate 311, an outer side plate 312A, and an inner side plate 312B, both vertically aligned on the bottom plate 311. Adjacent to the fan 25, the airflow divider is formed along the sides of the outer and inner side plates 312A and 312B, respectively, and includes the at least one intake port 32 and a divider outlet 33. In one embodiment, the intake port 32 is positioned between the ends of the side plates. Specifically, the outer side plates 312A are connected at one end to an inlet channel of the fan 25, while at least one inner side plate 312B is interposed therebetween. The end of the outer side plates 312A and the end of the inner side plate 312B form the intake port 32. The fan 25 directs the airflow into the airflow divider where it is divided into two or more streams. In alternative embodiments, the airflow channel may be implemented as an ventilation channel, with its plates integrally formed on the inner surfaces of either the first housing 11 or the second housing 21. The outer and inner side plates 312A and 312B guide one of the air streams discharged by the fan into the ventilation channel and, through the bottom plate 311, channel the airflow in the ventilation channel toward the exhaust assembly.

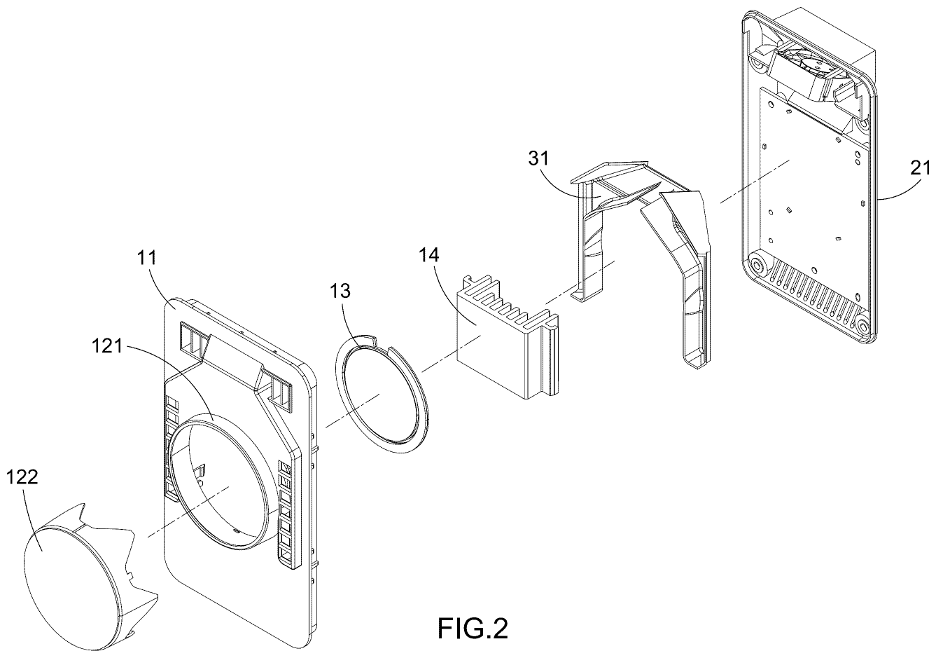

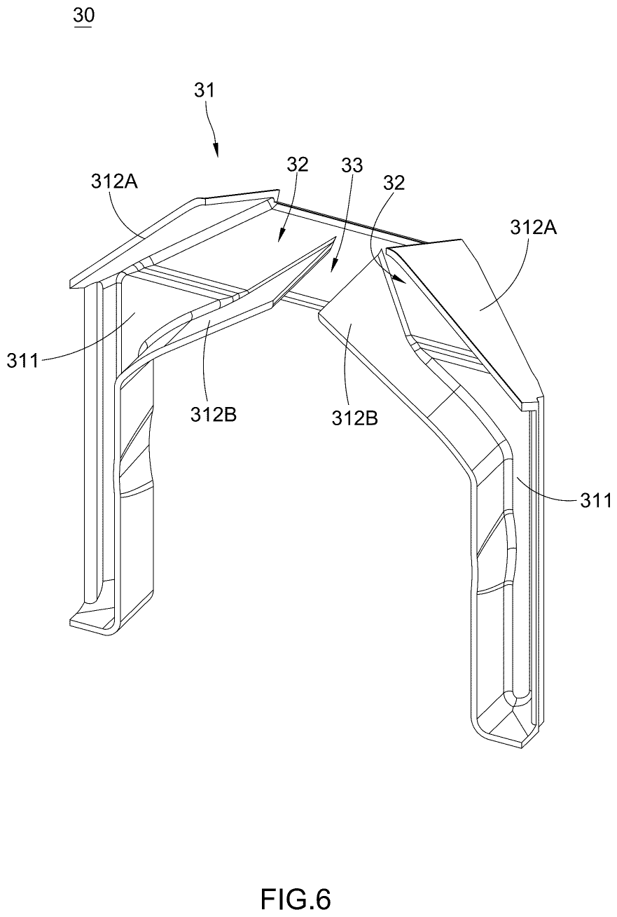

Refer to FIGS. 2 and 6, which show an embodiment of the present disclosure in which both the exhaust assemblies and the airflow channels are implemented in pairs. The exhaust vents 112a of the two exhaust assemblies are systematically arranged in an array along the left and right sides of the charging pad 12. Each airflow channel is symmetrically positioned with respect to the corresponding exhaust assembly and comprises the two inner side plates 312B positioned between the inlet channels defined by the two outer side plates 312A. The end of the outer side plates 312A and the end of the inner side plate 312B form the intake port 32, while the divider outlet 33 is located between the two inner side plates 312B and is positioned centrally between the two intake ports 32. The number of charging pads 12 is proportional to the number of the airflow guiding structures 30.

The airflow generated by the fan 25 is divided into multiple streams. One stream enters the ventilation channels via the two intake ports 32 formed between the outer and inner side plates 312A and 312B, and subsequently exits through the multiple exhaust vents 112a of the first housing 11 to dissipate heat from the mobile device. Another stream flows through the divider outlet 33 between the two inner side plates 312B, directed toward the heat sink 14, and exits through the air discharge zone 24 of the second housing 21 to enhance the thermal dissipation performance of the heat sink 14. This dual-stream configuration ensures robust airflow circulation, thereby achieving superior thermal management and device cooling. In alternative embodiments, a single exhaust assembly and airflow channel may be employed. In such configurations, the bottom plate 311 of the airflow channel may be circular in shape, with a vertically circular side plate extending from the bottom plate 311. The exhaust vents 112a in the exhaust assembly may then be arranged in a circular pattern surrounding the charging pad 12.

Furthermore, a protrusion height of the exhaust assembly is designed to be lower than that of the charging pad 12. This design not only minimizes the contact interface between the mobile device and the wireless charging device 100 but also increases the airflow by elevating the height of the exhaust assembly and positioning the exhaust vents 112a closer to the mobile device, thereby improving the airflow and significantly enhancing heat dissipation efficiency.

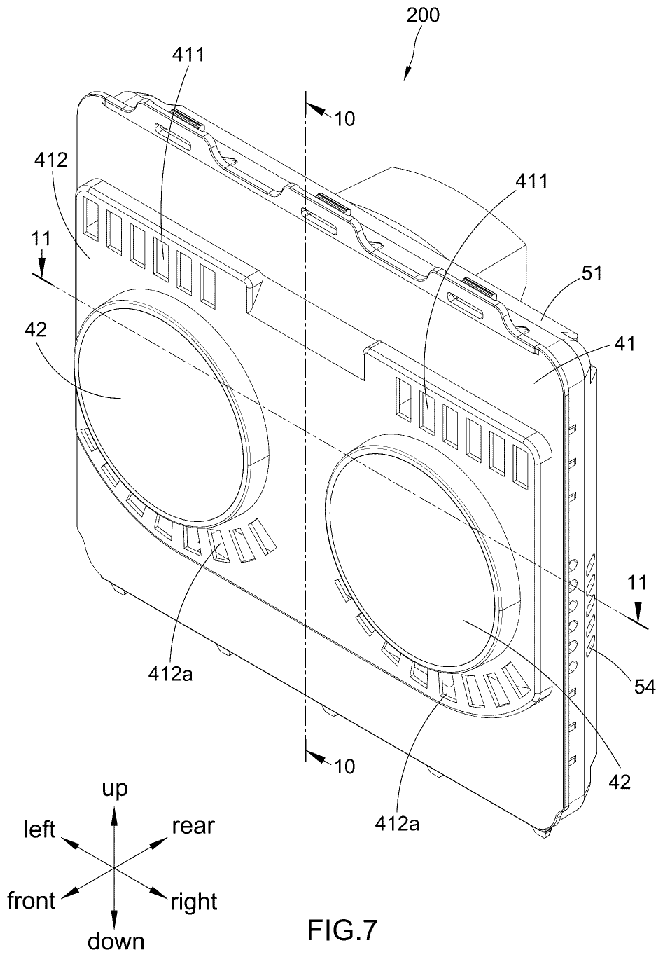

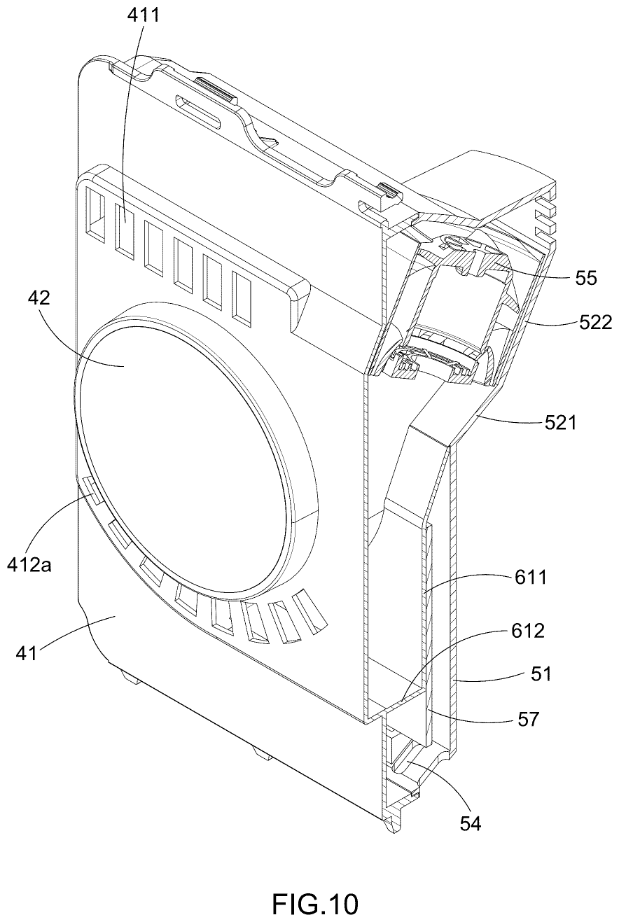

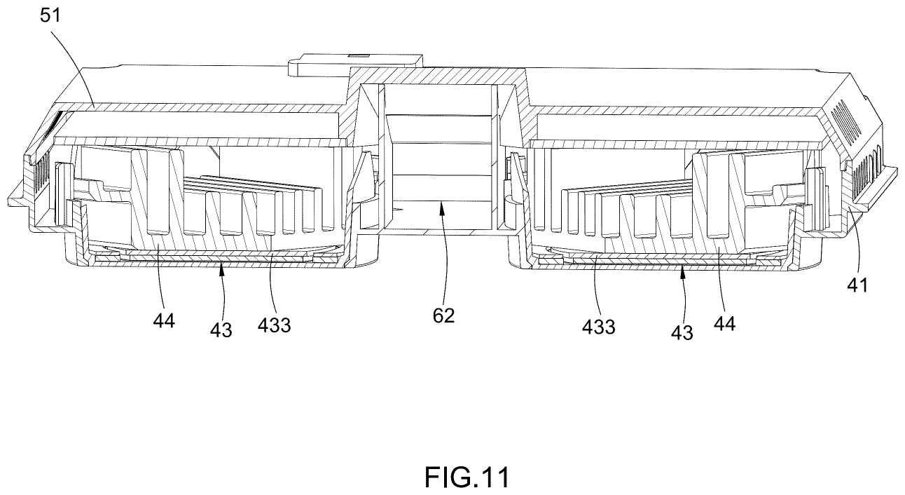

Refer to FIGS. 7 to 11, which show a second embodiment of the present disclosure comprising the wireless charging device 200. This device comprises a housing having a first housing 41 and a second housing 51. The first housing 41 integrates two charging pads 42, two intake grilles 411, and an exhaust assembly. The two charging pads 42 are laterally spaced to facilitate simultaneous charging of two mobile devices. The intake grilles 411 are positioned above each charging pad 42 and introduce external airflow. Each charging pad 42 houses a wireless charging coil module 43, with a heat sink 44 mounted behind a wireless charging coil 433 of the wireless charging coil module 43 to efficiently dissipate heat generated during operation.

As shown in FIG. 7, the exhaust assembly comprises an airflow guide panel 412 that extends vertically from an outer surface of the first housing 41 and is oriented opposite the second housing 51. The airflow guide panel 412 is equipped with multiple exhaust vents 412a on the surface, positioned below each of the two charging pads 42. These exhaust vents 412a can be arranged to encircle the charging pads 42 entirely or be arranged in arrays on the left and right sides of the charging pads 42.

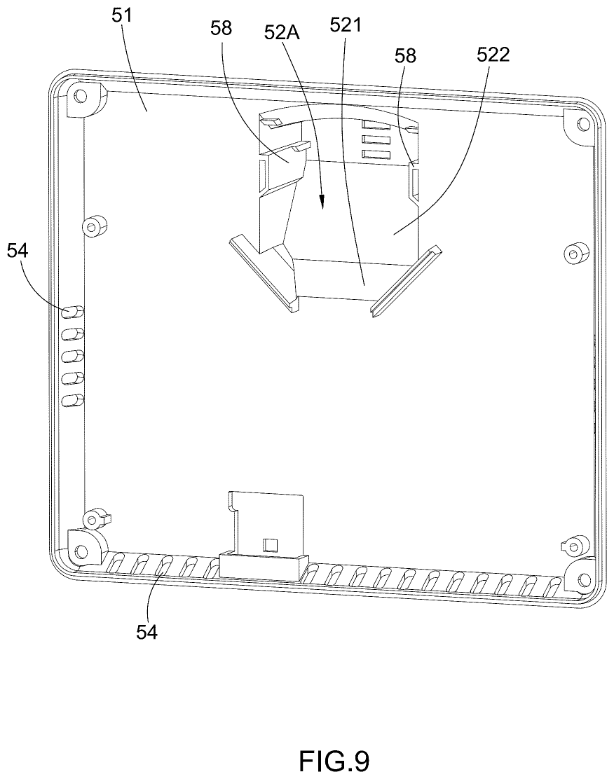

FIG. 9 highlights the second housing 51, which integrates a fan mount 52A and multiple air discharge zones 54. These air discharge zones 54 are placed along the lower and lateral sides of the second housing 51 to expedite airflow discharge. The fan mount 52A is located centrally between the two intake grilles 411 and includes a guide surface 521 and a support surface 522. The guide surface 521 is inclined relative to the second housing 51 and forms an angle of more than 100 degrees with the support surface 522. This inclined configuration reduces air resistance, optimizes airflow routing, and enhances heat dissipation efficiency.

In this embodiment, two alignment blocks 58 are affixed to the support surface 522 of the fan mount 52A to ensure the stable installation of the fan 55. Alternatively, the fan 55 may be secured on the fan mount 52A using fasteners such as bolts. In addition, a circuit board 57 is mounted on the inner surface of the second housing 51, and the fan 55 is electrically connected to the circuit board 57.

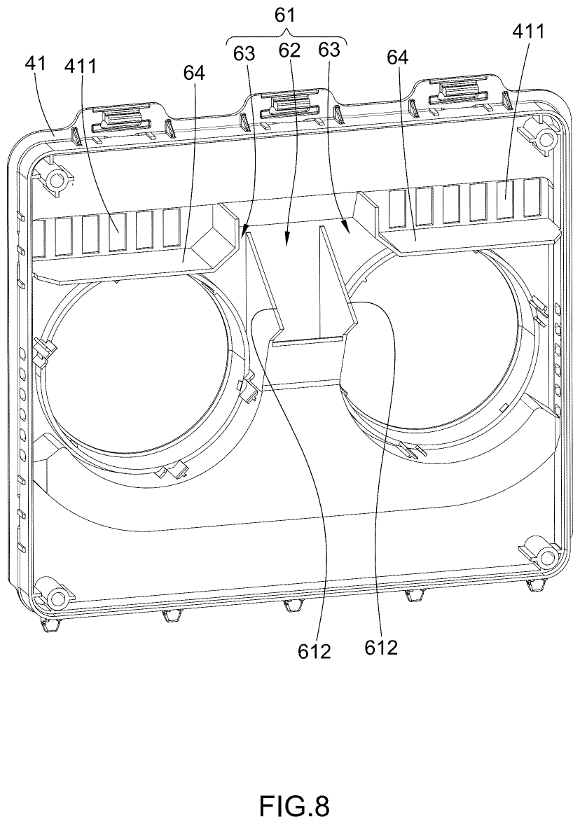

Refer to FIGS. 8, 10, and 11, where the airflow guiding structure constructed by the plates is integrated into the first housing 41 in the second embodiment. The airflow guiding structure includes an airflow divider 61, positioned to align with the exhaust assembly on the inner surface of the first housing 41. This airflow divider 61 comprises a bottom plate 611 and a side plate 612. The bottom plate 611 is aligned with the exhaust vents 412a and has a larger surface area than the total area of these exhaust vents to facilitate efficient airflow management. The side plate 612 extends vertically around the bottom plate 611 and the end of the side plate 612 is positioned within an inlet channel of the fan 55, forming an intake port 62 between the ends of the two side plates 612. In addition, an ventilation channel is formed between the airflow divider 61 and the first housing 41.

Moreover, the first housing 41 is further equipped with two flow guide plates 64, each corresponding to one of the intake grilles 411 on the inner surface of the first housing 41 (see FIG. 8). The ends of the two flow guide plates 64 are connected to the inlet channel of the fan 55, forming a common boundary between the intake grilles 411 and the inlet channel of the fan 55. These flow guide plates 64 are specifically designed to direct the airflow from the intake grilles 411 toward the fan 55. In addition, each flow guide plate 64 forms a divider outlet 63 with one end of the side plate 612. In this second embodiment, the external airflow enters through the two intake grilles 411 positioned on the left and right sides of the first housing 41, is directed to the fan 55 via the flow guide plates 64, and subsequently flows into the airflow divider 61.

In the second embodiment, the direction of the airflow passing through the divider outlet 63 is different from that in the first embodiment. Specifically, the airflow expelled by the fan 55 enters the airflow divider 61, where one portion of the airflow passes through the ventilation channel formed between the two side plates 612 via the intake port 62 and exits through the multiple exhaust vents 412a of the first housing 41 directed toward the two mobile devices connected to the charging pads 42 to dissipate the heat. Another portion of the airflow passes through the two divider outlets 63 located between the side plate 612 and the flow guide plate 64, directing the airflow toward the heat sinks 44 of the two charging pads 42. This airflow is expelled through the multiple air discharge zones 54 in the second housing 51, accelerating the heat dissipation performance of the heat sinks 44. This configuration ensures simultaneous charging and efficient thermal management of both the mobile devices and the heat sinks 44, thereby achieving optimal cooling effects.

In all embodiments of the present disclosure, the heat sinks 14, 44 are positioned directly behind the wireless charging coil modules 13, 43. The incorporation of the airflow dividers 31, 61 enables the airflow generated by the fans 25, 55 to be effectively directed toward the heat sinks 14, 44. In addition, the protruding design of the charging pads 12, 42 minimizes the contact area between the mobile devices and the wireless charging devices 100, 200. This configuration allows the airflow discharged from the fans 25, 55 through the exhaust vents 112a, 412a to be directed to the outer surfaces of the mobile devices, enhancing the heat dissipation efficiency. Consequently, the present disclosure enables the airflow from the fans 25, 55 to simultaneously cool the heat sinks 14, 44 and the mobile devices, thereby reducing the heat generated during charging. Moreover, the simplified structural design of the present disclosure can also ensure cost-effective production while maintaining robust heat dissipation performance.

What is claimed is:

1. A wireless charging device with a heat dissipation structure, comprising:
a housing comprising at least one charging pad, at least one intake grille, and at least one exhaust assembly, wherein the at least one charging pad protrudes from an outer surface of the housing, and including a wireless charging coil module and a heat sink, the heat sink being positioned on one side of the wireless charging coil module;
a fan positioned within the housing; and
an airflow guiding structure positioned within the housing and including an airflow divider and at least one airflow channel,
wherein the airflow divider is positioned within the housing and adjacent to the fan, the airflow divider including at least one intake port and a divider outlet configured to divide the airflow discharged from the fan into multiple streams directed toward the divider outlet and the at least one intake port, respectively, and
wherein the at least one airflow channel is positioned within the housing and constructed to connect the intake port with the exhaust assembly.

2. The wireless charging device with a heat dissipation structure according to claim 1, wherein the housing further comprises a first housing and a second housing combined with each other, wherein the at least one charging pad includes an alignment ring and a protective lid, the alignment ring extending vertically from an outer surface of the first housing in a direction opposite the second housing, the protective lid being mounted on the alignment ring to form an accommodation space with the alignment ring, and the wireless charging coil module is positioned within the accommodation space.

3. The wireless charging device with a heat dissipation structure according to

2. wherein the second housing includes a fan mount and at least one air discharge zone located on two sides of the second housing, the fan mount being located to correspond to the position of the intake grille.

4. The wireless charging device with a heat dissipation structure according to claim 3, wherein the fan mount has a mounting plate extending outward from the second housing in a direction opposite the first housing, the mounting plate including a guide surface and a support surface, wherein an angle is formed between the support surface and the guide surface, the guide surface being inclined relative to the second housing, and wherein the fan is mounted on the support surface.

5. The wireless charging device with a heat dissipation structure according to claim 2, wherein the at least one exhaust assembly has an airflow guide panel extending vertically from an outer surface of the first housing in the direction opposite the second housing, the airflow guide panel having a surface with multiple exhaust vents arranged in an array form on either the left or right side of the at least one charging pad.

6. The wireless charging device with a heat dissipation structure according to claim 5, wherein a protrusion height of the exhaust assembly is lower than a protrusion height of the charging pad.

7. The wireless charging device with a heat dissipation structure according to claim 5, wherein the surface of the airflow guide panel includes the multiple exhaust vents configured in a circular pattern, the exhaust vents being positioned to encircle the charging pad.

8. The wireless charging device with a heat dissipation structure according to claim 1, wherein the at least one airflow guiding structure is implemented as an ventilation channel.

9. The wireless charging device with a heat dissipation structure according to claim 8, wherein the ventilation channel includes at least one plate, the at least one plate being either assembled or integrally formed on an inner surface of the housing.

10. The wireless charging device with a heat dissipation structure according to claim 9, wherein the multiple exhaust vents of the at least one exhaust assembly are positioned on an upper surface of the housing.

11. The wireless charging device with a heat dissipation structure according to claim 1, wherein the airflow guiding structure includes a bottom plate and a side plate extending vertically from the bottom plate, one end of the side plate forming a boundary between the intake port and the divider outlet.

12. The wireless charging device with a heat dissipation structure according to claim 11, wherein the number of both the at least one exhaust assembly and the at least one airflow channel is two, each exhaust assembly includes the multiple exhaust vents arranged in an array, the two exhaust assemblies are symmetrically positioned on the left and right sides of the at least one charging pad, and the two airflow channels are symmetrically positioned to align with the two exhaust assemblies.

13. The wireless charging device with a heat dissipation structure according to claim 1, wherein the number of both the at least one charging pad and the at least one intake grille is two, the number of both the at least one exhaust assembly and the at least one airflow channel is one, and the exhaust assembly includes the multiple exhaust vents formed on one side of the two charging pads, respectively.

14. The wireless charging device with a heat dissipation structure according to claim 1, wherein the number of the at least one intake grille is two, a fan mount is positioned correspondingly between the two intake grilles, and the airflow guiding structure includes two flow guide plates corresponding to the two intake grilles.
